(19) United States
(12) Patent Application Publication
(10) Pub. No.: US 2025/0201602 A1
(43) Pub. Date: Jun. 19, 2025

(54) HYBRID BONDING APPARATUS

(71) Applicant: Samsung Electronics Co., Ltd., Suwon-si (KR)

(72) Inventors: Sunwoo Park, Suwon-si (KR); Minwoo Rhee, Suwon-si (KR); Mingu Lee, Suwon-si (KR); Seungdon Lee, Suwon-si (KR); Juhyung Lee, Suwon-si (KR); Hyunjin Lee, Suwon-si (KR); Ahra Jo, Suwon-si (KR); Euisun Choi, Suwon-si (KR)

(21) Appl. No.: 18/742,397

(22) Filed: Jun. 13, 2024

(30) Foreign Application Priority Data
Dec. 15, 2023 (KR) 10-2023-0182814

(51) Int. Cl. H01L 21/67

(52) U.S. Cl. CPC H01L 21/67253; H01L 21/67144

(57) ABSTRACT

A hybrid bonding apparatus may include a central pushing module, at least two edge pushing modules and a bonding tool. The central pushing module may apply a central pressure to a central portion of a semiconductor chip toward a package substrate. The at least two edge pushing modules may apply an edge pressure to edge portions of the semiconductor chip toward the package substrate. The bonding tool may transfer the central pressure and the edge pressure to the semiconductor chip. Thus, a hybrid bonding process for bonding the semiconductor chip to the package substrate may be progressed from the central portion of the semiconductor chip toward the edge portions of the semiconductor chip. As a result, a bubble caused by air or a particle may not be captured between the semiconductor chip and the package substrate to improve electrical connection reliability between the semiconductor chip and the package substrate.

### CROSS-RELATED APPLICATION

This application claims priority under 35 U.S.C. § 119 to Korean Patent Application No. 10-2023-0182814, filed on Dec. 15, 2023, in the Korean Intellectual Property Office (KIPO), the contents of which are herein incorporated by reference in their entirety.

### BACKGROUND

### 1. Field

Example embodiments relate to a hybrid bonding apparatus. More particularly, example embodiments relate to an apparatus configured to hybrid bond a semiconductor chip to a package substrate.

### 2. Description of the Related Art

A hybrid bonding process may use a hybrid bonding apparatus configured to directly bond a semiconductor chip to a package substrate without an adhesive or a conductive bump. The hybrid bonding apparatus may pressurize the semiconductor chip to the package substrate to directly bond the semiconductor chip to the package substrate.

According to related arts, a bubble caused by air or a particle may be generated between the semiconductor chip and the package substrate. The bubble may deteriorate electrical connection reliability between the semiconductor chip and the package substrate.

### SUMMARY

Example embodiments provide a hybrid bonding apparatus that may be capable of improving electrical connection reliability between a semiconductor chip and a package substrate.

According to example embodiments, there may be provided a hybrid bonding apparatus. The hybrid bonding apparatus may include a central pushing module, at least two edge pushing modules and a bonding tool. The central pushing module may apply a central pressure to a central portion of a semiconductor chip toward a package substrate. The at least two edge pushing modules may apply an edge pressure to edge portions of the semiconductor chip toward the package substrate. The bonding tool may transfer the central pressure and the edge pressure to the semiconductor chip.

According to example embodiments, there may be provided a hybrid bonding apparatus. The hybrid bonding apparatus may include a central pushing module, at least two edge pushing modules, a bonding tool and a controller. The central pushing module may primarily apply a central pressure to a central portion of a semiconductor chip toward a package substrate. The at least two edge pushing modules may secondarily apply an edge pressure to edge portions of the semiconductor chip toward the package substrate. The bonding tool may be arranged between the central pushing module and the semiconductor chip and between the edge pushing module and the semiconductor chip to transfer the central pressure and the edge pressure to the semiconductor chip. The controller may control operations of the central pushing module and the edge pushing modules.

According to example embodiments, after the central pushing module may apply the central pressure to the central portion of the semiconductor chip, the edge pushing modules may apply the edge pressure to the edge portions of the semiconductor chip. Thus, a hybrid bonding process for bonding the semiconductor chip to the package substrate may be progressed from the central portion of the semiconductor chip toward the edge portions of the semiconductor chip. As a result, a bubble caused by air or a particle may not be captured between the semiconductor chip and the package substrate to improve electrical connection reliability between the semiconductor chip and the package substrate.

### BRIEF DESCRIPTION OF THE DRAWINGS

Example embodiments will be more clearly understood from the following detailed description taken in conjunction with the accompanying drawings. FIGS. 1 to 8 represent non-limiting, example embodiments as described herein.

FIG. 1 is a cross-sectional view illustrating a hybrid bonding apparatus in accordance with example embodiments;

FIG. 2 is a bottom view illustrating the hybrid bonding apparatus in FIG. 1;

FIGS. 3 and 4 are cross-sectional views illustrating an operation of the hybrid bonding apparatus in FIG. 1;

FIG. 5 is a cross-sectional view illustrating a hybrid bonding apparatus in accordance with example embodiments; and

FIGS. 6 to 8 are cross-sectional views illustrating an operation of the hybrid bonding apparatus in FIG. 5.

### DETAILED DESCRIPTION OF THE EMBODIMENTS

Hereinafter, example embodiments will be explained in detail with reference to the accompanying drawings. Like reference characters refer to like elements throughout. As used herein, the term “contact” refers to a direct connection (i.e., touching) unless the context indicates otherwise. The term “air” as discussed herein, may refer to atmospheric air, or other gases that may be present during the manufacturing process.

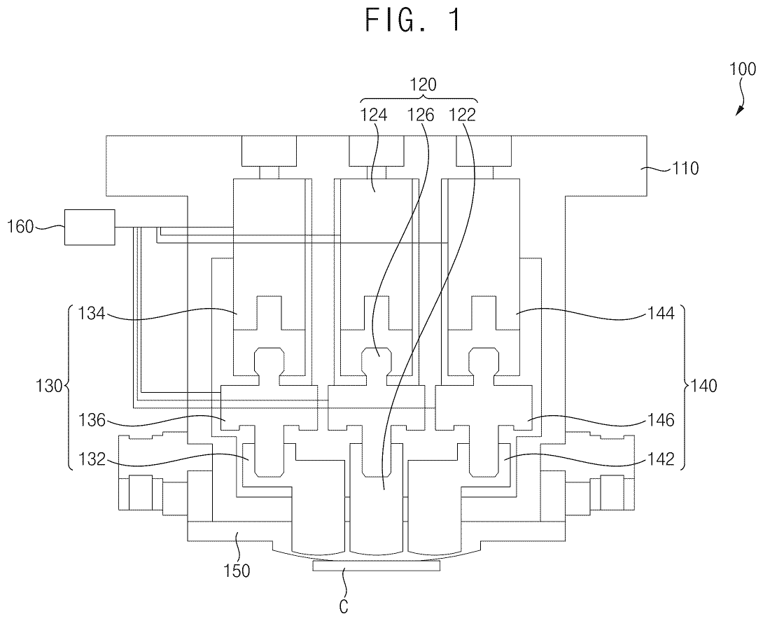

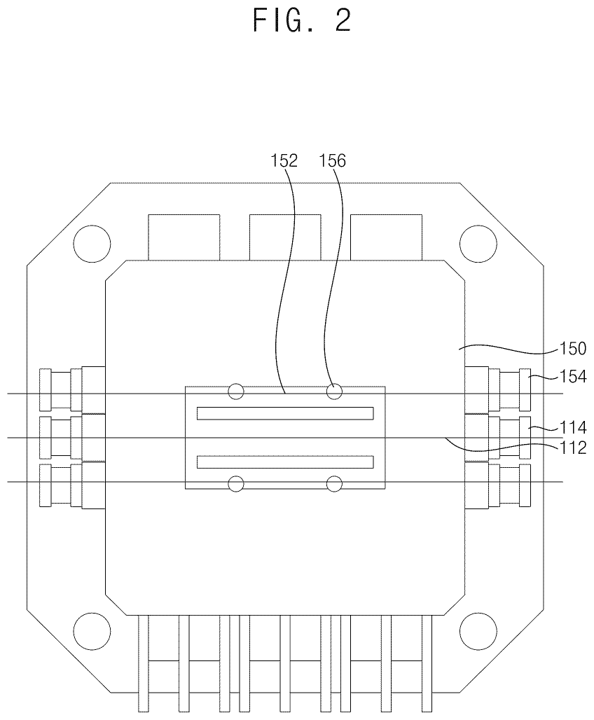

FIG. 1 is a cross-sectional view illustrating a hybrid bonding apparatus in accordance with example embodiments, and FIG. 2 is a bottom view illustrating the hybrid bonding apparatus in FIG. 1.

Referring to FIGS. 1 and 2, a hybrid bonding apparatus 100 of example embodiments may include a bonding block 110, a central pushing module 120, at least two edge pushing modules (e.g., a first edge pushing module 130 and a second edge pushing module 140), a bonding tool 150, and a controller 160.

The bonding block 110 may be configured to receive the central pushing module 120, the edge pushing modules, and the bonding tool 150. Particularly, the central pushing module 120 and the edge pushing modules may be arranged in the bonding block 110. The bonding tool 150 may be arranged at a lower surface of the bonding block 110.

In example embodiments, the bonding tool 150 may be detachably connected to the lower surface of the bonding block 110. Thus, the bonding tool 150 may be exchanged for a new bonding tool in accordance with a wear of the bonding tool 150. In order to exchange the bonding tool 150 for the new bonding tool, the bonding block 110 may include a vacuum line 112. The vacuum line 112 may be formed in the lower surface of the bonding block 110. The vacuum line 112 may be connected to a vacuum port 114 positioned at both sides of the lower surface of the bonding block 110. A vacuum may be introduced into the vacuum line 112 through the vacuum port 114.

The bonding tool 150 may thermally pressurize an upper surface of a semiconductor chip C. The bonding tool 150 may include a plurality of vacuum holes 156 configured to fix the semiconductor chip C. For example, the plurality of vacuum holes 156 may be configured to affix the semiconductor chip C to the bonding tool 150. The vacuum holes 156 may be four holes positioned at corners of a lower surface of the bonding tool 150, but embodiments are not limited thereto. The vacuum holes 156 may be connected to vacuum lines 152 extended from a vacuum port 154 positioned at both sides of the lower surface of the bonding tool 150. Vacuum may be introduced into the vacuum holes 156 through the vacuum port 154 and the vacuum line 152. The semiconductor chip C may be affixed to the bonding tool 150 by a vacuum pressure created by the vacuum introduced into the vacuum holes 156 through the vacuum port 154 and the vacuum line 152.

The central pushing module 120 may be arranged over a central portion of the upper surface of the semiconductor chip C. The central pushing module 120 may apply a central pressure to the central portion of the semiconductor chip C. Particularly, the central pushing module 120 may primarily apply the central pressure to the central portion of the semiconductor chip C. The central pushing module 120 may include a central pusher 122, a central actuator 124, and a central pressure sensor 126.

The central pusher 122 may be liftably arranged in the bonding block 110. For example, the central pusher 122 may be arranged in the bonding block 110 to be moveable in the upward and downward directions, which are directions substantially perpendicular to an upper surface of the semiconductor chip C. The central pusher 122 may apply the central pressure to the central portion of the semiconductor chip C. For example, when the central pusher 122 may be downwardly moved toward the semiconductor chip C, the central pressure may be applied to the central portion of the semiconductor chip C from the central pusher 122 through the bonding tool 150.

The central actuator 124 may be arranged in the bonding block 110. The central actuator 124 may lift the central pusher 122. For example, the central actuator 124 may move the central pusher 122 in an upward direction away from the semiconductor chip C. In example embodiments, the central actuator 124 may include a motor, but embodiments are not limited thereto. An operation of the central actuator 124 may be controlled by the controller 160.

The central pressure sensor 126 may be arranged between the central pusher 122 and the central actuator 124. The central pressure sensor 126 may measure the central pressure applied from the central pusher 122 to the central portion of the semiconductor chip C. The central pressure measured by the central pressure sensor 126 may be transmitted to the controller 160. In example embodiments, the central pressure sensor 126 may include a load cell, but embodiments are not limited thereto.

Each of the edge pushing modules may be arranged over an edge portion of the upper surface of the semiconductor chip C. The edge pushing module may apply an edge pressure to the edge portion of the semiconductor chip C. Particularly, the edge pushing module may secondarily apply the edge pressure to the edge portion of the semiconductor chip C. For example, after the central pushing module 120 applies the central pressure to the central portion of the semiconductor chip C, the edge pushing module may apply the edge pressure to the edge portion of the semiconductor chip C.

In example embodiments, the edge pushing modules may include a first edge pushing module 130 and a second edge pushing module 140. The first edge pushing module 130 may apply the edge pressure to a first edge portion, which may be positioned at one side of the central portion of the semiconductor chip C, among the edge portions of the semiconductor chip C. The second edge pushing module 140 may apply the edge pressure to a second edge portion, which may be positioned at the other side of the central portion of the semiconductor chip C, among the edge portions of the semiconductor chip C. For example, the first edge pushing module 130 and the second edge pushing module 140 may apply edge pressure to first and second edge portions, which may be positioned at opposite sides of the central portion of the semiconductor chip C.

The first edge pushing module 130 may include a first edge pusher 132, a first edge actuator 134, and a first edge pressure sensor 136.

The first edge pusher 132 may be liftably arranged in the bonding block 110. For example, the first edge pusher 132 may be arranged in the bonding block 110 to be moveable in the upward and downward directions, which are directions substantially perpendicular to an upper surface of the semiconductor chip C. The first edge pusher 132 may apply the edge pressure to the first edge portion of the semiconductor chip C. For example, when the first edge pusher 132 is downwardly moved toward the semiconductor chip C, the edge pressure may be applied to the first edge portion of the semiconductor chip C from the first edge pusher 132 through the bonding tool 150.

The first edge actuator 134 may be arranged in the bonding block 110. The first edge actuator 134 may lift the first edge pusher 132. For example, the first edge actuator 134 may move the first edge pusher 132 in an upward direction away from the semiconductor chip C. In example embodiments, the first edge actuator 134 may include a motor, but embodiments are not limited thereto. An operation of the first edge actuator 134 may be controlled by the controller 160.

The first edge pressure sensor 136 may be arranged between the first edge pusher 132 and the first edge actuator 134. The first edge pressure sensor 136 may measure the edge pressure applied from the first edge pusher 132 to the first edge portion of the semiconductor chip C. The edge pressure measured by the first edge pressure sensor 136 may be transmitted to the controller 160. In example embodiments, the first edge pressure sensor 136 may include a load cell, but embodiments are not limited thereto.

The second edge pushing module 140 may include a second edge pusher 142, a second edge actuator 144, and a second edge pressure sensor 146.

The second edge pusher 142 may be liftably arranged in the bonding block 110. For example, the second edge pusher 142 may be arranged in the bonding block 110 to be moveable in the upward and downward directions, which are directions substantially perpendicular to an upper surface of the semiconductor chip C. The second edge pusher 142 may apply the edge pressure to the second edge portion of the semiconductor chip C. For example, when the second edge pusher 142 is downwardly moved toward the semiconductor chip C, the edge pressure may be applied to the second edge portion of the semiconductor chip C from the second edge pusher 142 through the bonding tool 150.

The second edge actuator 144 may be arranged in the bonding block 110. The second edge actuator 144 may lift the second edge pusher 142. For example, the second edge actuator 144 may move the second edge pusher 142 in an upward direction away from the semiconductor chip C. In example embodiments, the second edge actuator 144 may include a motor, but embodiments are not limited thereto. An operation of the second edge actuator 144 may be controlled by the controller 160.

The second edge pressure sensor 146 may be arranged between the second edge pusher 142 and the second edge actuator 144. The second edge pressure sensor 146 may measure the edge pressure applied from the second edge pusher 142 to the second edge portion of the semiconductor chip C. The edge pressure measured by the second edge pressure sensor 146 may be transmitted to the controller 160. In example embodiments, the second edge pressure sensor 146 may include a load cell, but embodiments are not limited thereto.

The controller 160 may control the operations of the central pushing module 120 and the first and second edge pushing modules 130 and 140. Particularly, the controller 160 may control the central pushing module 120 and the first and second edge pushing modules 130 and 140 to apply the edge pressure to the first and second edge portions of the semiconductor chip C after applying the central pressure to the central portion of the semiconductor chip C. For example, the controller 1650 may operate the central pushing module 120. Thus, the central pressure may be applied to the central portion of the semiconductor chip C from the central pusher 122. The controller 160 may then operate the first and second edge pushing modules 130 and 140 when the central pushing module 120 is operated. Thus, the edge pressure may be applied to the first and second edge portions of the semiconductor chip C from the first and second edge pushers 132 and 142, respectively. For example, the hybrid bonding process may be progressed from the central portion to the edge portions in the semiconductor chip C. As a result, a bubble caused by air or a particle may not be trapped between the semiconductor chip C and a package substrate to thereby improve electrical connection reliability between the semiconductor chip C and the package substrate.

Further, the controller 160 may receive the central pressure measured by the central pressure sensor 126. The controller 160 may control the central actuator 124 in accordance with the central pressure to change the central pressure applied from the central pusher 122 to the central portion of the semiconductor chip C. Thus, an optimal central pressure for hybrid bonding the central portion of the semiconductor chip C to the package substrate may be applied to the central portion of the semiconductor chip C. The controller 160 may receive the edge pressure measured by the first and second edge pressure sensors 136 and 146. The controller 160 may control the first and second edge actuators 134 and 144 in accordance with the edge pressure to change the edge pressure applied from the first and second edge pushers 132 and 142 to the first and second edge portions of the semiconductor chip C. Thus, an optimal edge pressure for hybrid bonding the first and second edge portions of the semiconductor chip C to the package substrate may be applied to the first and second edge portions of the semiconductor chip C.

Although not illustrated, the controller 160 can include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 160 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller can include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

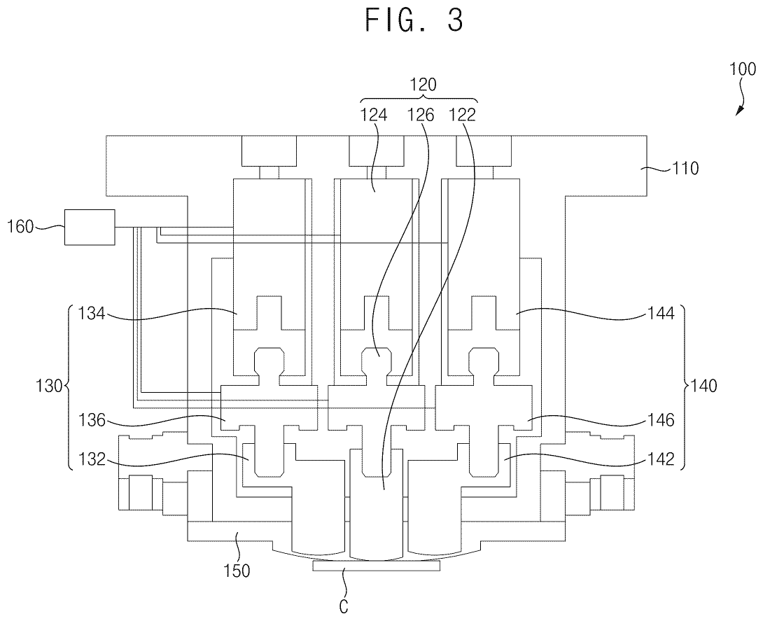

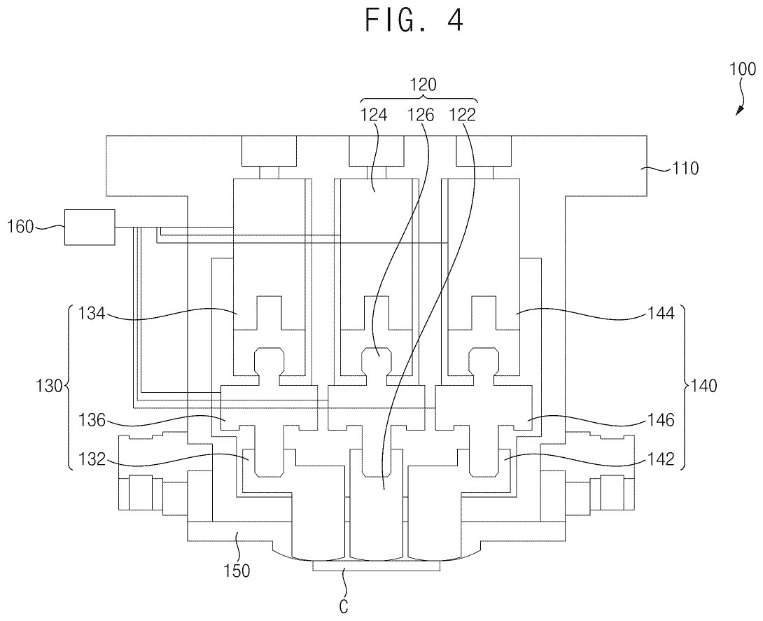

FIGS. 3 and 4 are cross-sectional views illustrating an operation of the hybrid bonding apparatus in FIG. 1.

Referring to FIG. 3, the controller 160 may operate the central pushing module 120. For example, the controller 160 may operate the central actuator 124. The central pusher 122 may be downwardly moved by the central actuator 124 toward the semiconductor chip C. Thus, the central portion of the semiconductor chip C may be downwardly pressurized by the central pusher 122 to contact the central portion of the bonding tool 150 with the central portion of the semiconductor chip C. Therefore, the central pressure may be applied to the central portion of the semiconductor chip C through the central portion of the bonding tool 150.

Referring to FIG. 4, the controller 160 may then operate the first and second edge pushing modules 130 and 140. For example, the controller 160 may operate the first and second edge actuators 134 and 144. The first and second edge pushers 132 and 142 may be downwardly moved by the first and second edge actuators 134 and 144 toward the semiconductor chip C. Thus, the first and second edge portions of the semiconductor chip C may be downwardly pressurized by the first and second edge pushers 132 and 142 to contact the edge portions of the bonding tool 150 with the first and second edge portions of the semiconductor chip C. Therefore, the edge pressure may be applied to the first and second edge portions of the semiconductor chip C through the edge portions of the bonding tool 150.

Therefore, after applying the central pressure to the central portion of the semiconductor chip C, the edge pressure may then be applied to the edge portions of the semiconductor chip C. For example, the hybrid bonding process may be progressed from the central portion to the edge portions in the semiconductor chip C. As a result, the bubble caused by the air or the particle may not be trapped between the semiconductor chip C and the package substrate, thereby improving the electrical connection reliability between the semiconductor chip C and the package substrate.

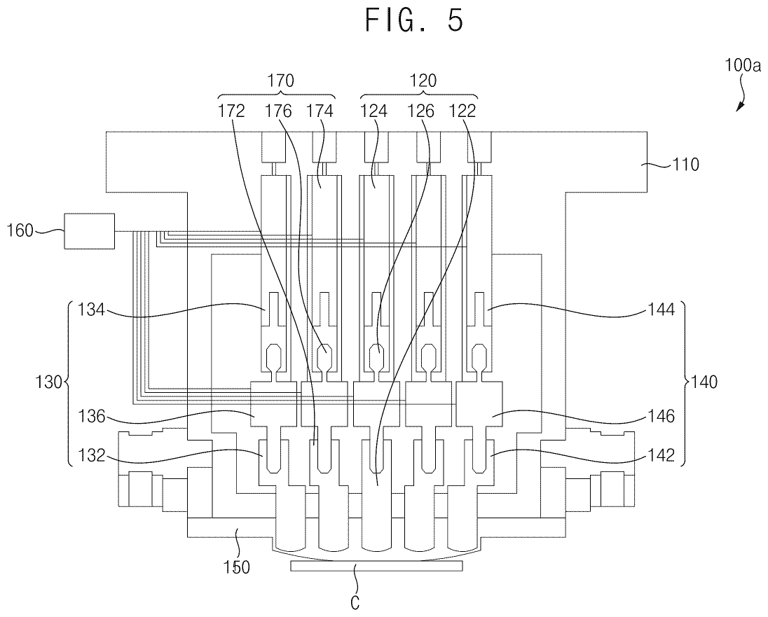

FIG. 5 is a cross-sectional view illustrating a hybrid bonding apparatus in accordance with example embodiments.

A hybrid bonding apparatus 100a of example embodiments may include elements substantially the same as those of the hybrid bonding apparatus 100 in FIG. 1 except for further including a middle pushing module 170. Thus, the same reference numerals may refer to the same elements and any further illustrations with respect to the same elements may be omitted herein for brevity.

Referring to FIG. 5, the hybrid bonding apparatus 100a of example embodiments may further include the at least two middle pushing modules 170.

The middle pushing modules 170 may be arranged over a middle portion of the upper surface of the semiconductor chip C. The middle pushing modules 170 may apply a middle pressure to a middle portion of the semiconductor chip C. The middle portion of the semiconductor chip C may be a portion between the center portion of the semiconductor chip C and the edge portion of the semiconductor chip C. Particularly, the middle pushing modules 170 may be operated between the operation of the central pushing module 120 and the operation of the first and second edge pushing modules 130 and 140. For example, the middle pushing modules 170 may be operated after operating the central pushing module 120. The first and second edge pushing modules 130 and 140 may be operated after operating the middle pushing modules 170. The middle pushing module 170 may include a middle pusher 172, a middle actuator 174, and a middle pressure sensor 176.

The middle pusher 172 may be liftably arranged in the bonding block 110. For example, the middle pusher 172 may be arranged in the bonding block 110 to be moveable in the upward and downward directions, which are directions perpendicular to an upper surface of the semiconductor chip C. The middle pusher 172 may apply the middle pressure to the middle portion of the semiconductor chip C. For example, when the middle pusher 172 is downwardly moved toward the semiconductor chip C, the middle pressure may be applied to the middle portion of the semiconductor chip C from the middle pusher 172 through the bonding tool 150.

The middle actuator 174 may be arranged in the bonding block 110. The middle actuator 174 may lift the middle pusher 172. For example, the middle actuator 174 may move the middle pusher 172 in an upward direction away from the semiconductor chip C. In example embodiments, the middle actuator 174 may include a motor, but embodiments are not limited thereto. An operation of the middle actuator 174 may be controlled by the controller 160.

The middle pressure sensor 176 may be arranged between the middle pusher 172 and the middle actuator 174. The middle pressure sensor 176 may measure the middle pressure applied from the middle pusher 172 to the middle portion of the semiconductor chip C. The middle pressure measured by the middle pressure sensor 176 may be transmitted to the controller 160. In example embodiments, the middle pressure sensor 176 may include a load cell, but embodiments are not limited thereto.

The controller 160 may control the operations of the middle pushing modules 170. Particularly, the controller 160 may control the central pushing module 120, the middle pushing modules 170, and the first and second edge pushing modules 130 and 140 to apply the middle pressure to the middle portion of the semiconductor chip C between the applying of the central pressure to the central portion of the semiconductor chip C and the applying of the edge pressure to the first and second edge portions of the semiconductor chip C. For example, the hybrid bonding process may be progressed from the central portion to the edge portions through the middle portion in the semiconductor chip C. As a result, a bubble caused by air or a particle may not be trapped between the semiconductor chip C and a package substrate, thereby improving electrical connection reliability between the semiconductor chip C and the package substrate.

Further, the controller 160 may receive the middle pressure measured by the middle pressure sensor 176. The controller 160 may control the middle actuator 174 in accordance with the middle pressure to change the middle pressure applied from the middle pusher 172 to the middle portion of the semiconductor chip C. Thus, an optimal middle pressure for hybrid bonding the middle portion of the semiconductor chip C to the package substrate may be applied to the middle portion of the semiconductor chip C.

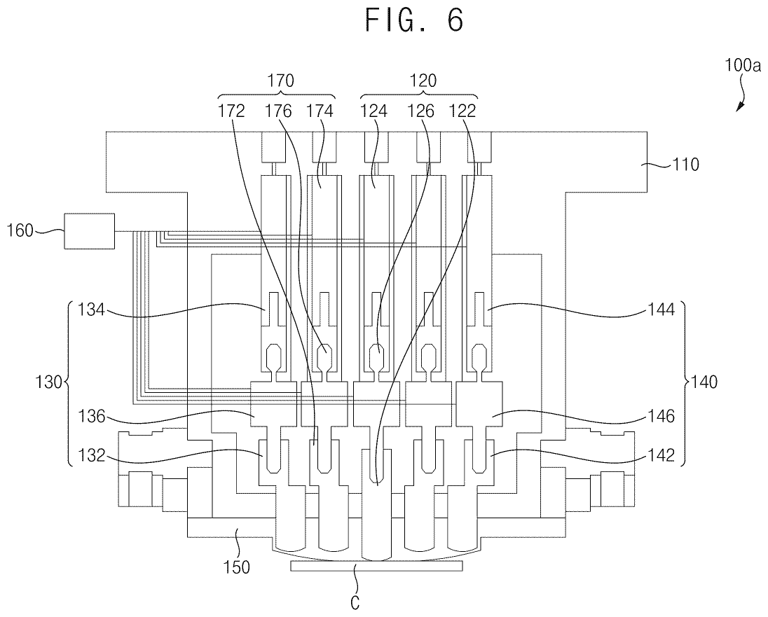

FIGS. 6 to 8 are cross-sectional views illustrating an operation of the hybrid bonding apparatus in FIG. 5.

Referring to FIG. 6, the controller 160 may operate the central pushing module 120. For example, the controller 160 may operate the central actuator 124. The central pusher 122 may be downwardly moved by the central actuator 124 toward the semiconductor chip C. Thus, the central portion of the semiconductor chip C may be downwardly pressurized by the central pusher 122 to contact the central portion of the bonding tool 150 with the central portion of the semiconductor chip C. Therefore, the central pressure may be applied to the central portion of the semiconductor chip C through the central portion of the bonding tool 150.

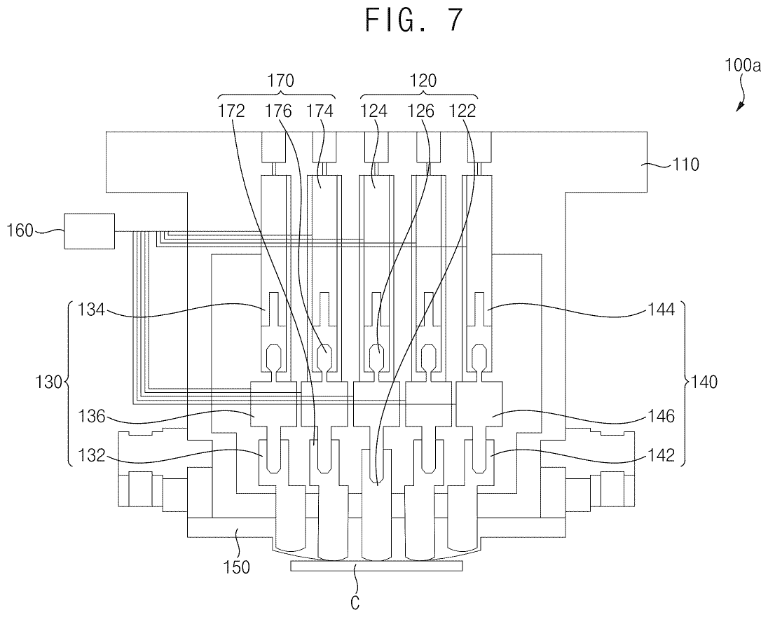

Referring to FIG. 7, the controller 160 may then operate the middle pushing module 170. For example, the controller 160 may operate the middle actuator 174. The middle pusher 172 may be downwardly moved by the middle actuator 174 toward the semiconductor chip C. Thus, the middle portion of the semiconductor chip C may be downwardly pressurized by the middle pusher 172 to contact the middle portion of the bonding tool 150 with the middle portion of the semiconductor chip C. Therefore, the middle pressure may be applied to the middle portion of the semiconductor chip C through the middle portion of the bonding tool 150.

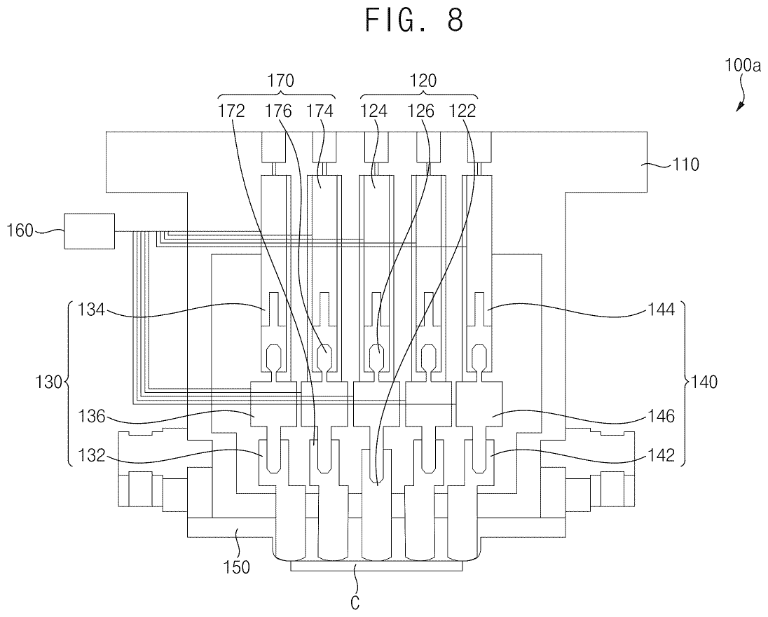

Referring to FIG. 8, the controller 160 may then operate the first and second edge pushing modules 130 and 140. For example, the controller 160 may operate the first and second edge actuators 134 and 144. The first and second edge pushers 132 and 142 may be downwardly moved by the first and second edge actuators 134 and 144 toward the semiconductor chip C. Thus, the first and second edge portions of the semiconductor chip C may be downwardly pressurized by the first and second edge pushers 132 and 142 to contact the edge portions of the bonding tool 150 with the first and second edge portions of the semiconductor chip C. Therefore, the edge pressure may be applied to the first and second edge portions of the semiconductor chip C through the edge portions of the bonding tool 150.

Therefore, after applying the central pressure to the central portion of the semiconductor chip C, the middle pressure may then be applied to the middle portions of the semiconductor chip C. The edge pressure may then be applied to the edge portion of the semiconductor chip C. For example, the hybrid bonding process may be progressed from the central portion to the edge portions through the middle portion in the semiconductor chip C. As a result, the bubble caused by the air or the particle may not be trapped between the semiconductor chip C and the package substrate, thereby improving the electrical connection reliability between the semiconductor chip C and the package substrate.

According to example embodiments, after the central pushing module applies the central pressure to the central portion of the semiconductor chip, the edge pushing modules may apply the edge pressure to the edge portions of the semiconductor chip. Thus, the hybrid bonding process for bonding the semiconductor chip to the package substrate may be progressed from the central portion of the semiconductor chip toward the edge portions of the semiconductor chip. As a result, the bubble caused by the air or the particle may not be captured between the semiconductor chip and the package substrate, thereby improving electrical connection reliability between the semiconductor chip and the package substrate.

The foregoing is illustrative of example embodiments and is not to be construed as limiting thereof. Although a few example embodiments have been described, those skilled in the art will readily appreciate that many modifications are possible in the example embodiments without droplet departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A hybrid bonding apparatus comprising:
a central pushing module configured to apply a central pressure to a central portion of a semiconductor chip toward a package substrate;
at least two edge pushing modules configured to apply an edge pressure to edge portions of the semiconductor chip toward the package substrate; and
a bonding tool configured to transfer the central pressure and the edge pressure to the semiconductor chip.

2. The hybrid bonding apparatus of claim 1, further comprising:
a controller configured to control operations of the central pushing module and the at least two edge pushing modules to apply the edge pressure to the edge portions of the semiconductor chip after applying the central pressure to the central portion of the semiconductor chip.

3. The hybrid bonding apparatus of claim 1, wherein the central pushing module comprises:
a central pusher configured to apply the central pressure to the central portion of the semiconductor chip; and
a central actuator configured to move the central pusher toward the central portion of the semiconductor chip.

4. The hybrid bonding apparatus of claim 3, wherein the central actuator comprises a motor.

5. The hybrid bonding apparatus of claim 3, wherein the central pushing module further comprises a central pressure sensor arranged between the central pusher and the central actuator to measure the central pressure by the central pusher.

6. The hybrid bonding apparatus of claim 5, wherein the central pressure sensor comprises a load cell.

7. The hybrid bonding apparatus of claim 1, wherein the at least two edge pushing modules comprise:
a first edge pushing module configured to apply the edge pressure to a first edge portion, which is positioned at one side of the central portion of the semiconductor chip, among the edge portions of the semiconductor chip; and
a second edge pushing module configured to apply the edge pressure to a second edge portion, which is positioned at the other side of the central portion of the semiconductor chip, among the edge portions of the semiconductor chip.

8. The hybrid bonding apparatus of claim 7, wherein each of the first and second edge pushing modules comprises:
an edge pusher configured to apply the edge pressure to a corresponding one of the first and second edge portions of the semiconductor chip; and
an edge actuator configured to move the edge pusher toward the corresponding one of the edge portions of the semiconductor chip.

9. The hybrid bonding apparatus of claim 8, wherein the edge actuator comprises a motor.

10. The hybrid bonding apparatus of claim 8, wherein each of the first and second edge pushing modules further comprises an edge pressure sensor arranged between the edge pusher and the edge actuator to measure the edge pressure by the edge pusher.

11. The hybrid bonding apparatus of claim 10, wherein the edge pressure sensor comprises a load cell.

12. The hybrid bonding apparatus of claim 1, further comprising at least two middle pushing modules configured to apply a middle pressure to middle portions of the semiconductor chip.

13. The hybrid bonding apparatus of claim 12, wherein each of the middle pushing modules comprises:
a middle pusher configured to apply the middle pressure to one of the middle portions of the semiconductor chip; and
a middle actuator configured to move the middle pusher toward the one of the middle portions of the semiconductor chip.

14. The hybrid bonding apparatus of claim 13, wherein the middle actuator comprises a motor.

15. The hybrid bonding apparatus of claim 13, wherein each of the middle pushing modules further comprises a middle pressure sensor arranged between the middle pusher and the middle actuator to measure the middle pressure by the middle pusher.

16. The hybrid bonding apparatus of claim 1, wherein the bonding tool comprises a plurality of vacuum holes for fixing the semiconductor chip.

17. The hybrid bonding apparatus of claim 8, further comprising a bonding block configured to receive the central pushing module, the at least two edge pushing modules and the bonding tool.

18. A hybrid bonding apparatus comprising:
a central pushing module configured to apply a central pressure to a central portion of a semiconductor chip toward a package substrate;
at least two edge pushing modules configured to apply an edge pressure to edge portions of the semiconductor chip toward the package substrate;
a bonding tool arranged between the central pushing module and the semiconductor chip and between the at least two edge pushing modules and the semiconductor chip to transfer the central pressure and the edge pressure to the semiconductor chip; and
a controller configured to control operations of the central pushing module and the at least two edge pushing modules.

19. The hybrid bonding apparatus of claim 18, wherein the central pushing module comprises:
a central pusher configured to apply the central pressure to the central portion of the semiconductor chip;
a central actuator configured to move the central pusher toward the central portion of the semiconductor chip; and
a central pressure sensor arranged between the central pusher and the central actuator to measure the central pressure by the central pusher.

20. The hybrid bonding apparatus of claim 18, wherein each of the at least two edge pushing modules comprises:
an edge pusher configured to apply the edge pressure to one of the edge portions of the semiconductor chip;
an edge actuator configured to move the edge pusher toward the one of the edge portions of the semiconductor chip; and
an edge pressure sensor arranged between the edge pusher and the edge actuator to measure the edge pressure by the edge pusher.
